(19) United States
(12) Patent Application Publication
(10) Pub. No.: US 2007/0281472 A1
(43) Pub. Date: Dec. 6, 2007

(54) METHOD OF INCREASING TRANSISTOR PERFORMANCE BY DOPANT ACTIVATION AFTER SILICIDATION

(76) Inventors: Patrick Press, Dresden (DE); Thomas Feudel, Radebeul (DE); Joe Bloomquist, Dresden (DE); Manfred Horstmann, Duehrrroehrsdorf-Dittersbach (DE)

Correspondence Address: WILLIAMS, MORGAN & AMERSON, 10333 RICHMOND, SUITE 1100, HOUSTON, TX, 77042, US

(21) Appl. No.: 11/622,088

(22) Filed: Jan. 11, 2007

(30) Foreign Application Priority Data
May 31, 2006 (DE) 10 2006 025 408.2

(51) Int. Cl. H01L 21/44

(52) U.S. Cl. 438/664

(57) ABSTRACT

By performing a laser-based or flash-based anneal process after silicidation, the degree of dopant activation with reduced diffusion activity may be accomplished, while the characteristics of the metal silicide may be improved or the complexity for manufacturing the same may be reduced.

### BACKGROUND OF THE INVENTION

1. Field of the Invention

Generally, the present disclosure relates to the formation of integrated circuits, and, more particularly, to an integration scheme for enhancing performance characteristics of MOS transistors.

2. Description of the Related Art

The fabrication of integrated circuits requires the formation of a large number of circuit elements on a given chip area according to a specified circuit layout. Generally, a plurality of process technologies are currently practiced, wherein, for complex circuitry, such as microprocessors, storage chips and the like, MOS technology is currently one of the most promising approaches, due to the superior characteristics in view of operating speed and/or power consumption and/or cost efficiency. During the fabrication of complex integrated circuits using MOS technology, millions of field effect transistors, e.g., N-channel transistors and P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely doped channel region disposed between the drain region and the source region.

The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on the dopant concentration, the dopant gradient at the PN junctions, the mobility of the charge carriers, and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region, in combination with the characteristics of the PN junctions, substantially determines the performance of MOS transistors. Thus, the reduction of the channel length, and associated therewith the reduction of the channel resistivity, renders the channel length a dominant design criterion for accomplishing an increase in the operating speed of the integrated circuits.

The reduction of the transistor dimensions, however, creates a plurality of issues associated therewith that have to be addressed so as to not unduly offset the advantages obtained by steadily decreasing the channel length of MOS transistors. There are challenging issues to be dealt with for the development of enhanced photolithography and etch strategies to reliably and reproducibly create circuit elements of critical dimensions, such as the gate electrode of the transistors, for a new device generation having reduced features sizes. Moreover, highly sophisticated dopant profiles, in the vertical direction as well as in the lateral direction, are required in the drain and source regions to provide low sheet and contact resistivity in combination with a desired channel controllability. In addition, the vertical location of the PN junctions with respect to the gate insulation layer also represents a critical design criterion in view of leakage current control. Hence, reducing the channel length also requires reducing the depth of the drain and source regions with respect to the interface formed by the gate insulation layer and the channel region, thereby requiring sophisticated implantation techniques and subsequent anneal processes.

In addition to the location of the PN junctions, the characteristics thereof, that is the dopant concentration and the gradient of the concentration, may significantly determine the characteristics of the device. For example, an abrupt junction may enhance transistor performance compared to a “blurred” PN junction. Thus, for highly advanced transistors, the positioning, shaping and maintaining of a desired dopant profile are important properties for defining the final performance of the device. In particular, when extremely shallow PN junctions with high dopant concentrations are required, the introduction of the dopant species as well as the activation thereof are challenging tasks. Typically, the dopant species is introduced by ion implantation, wherein dose and energy, in combination with the process time, determine the location and shape of the implant region, wherein the degree of lattice damage is also determined by the implantation parameters. Since the dopant atoms may contribute to the required charge carrier density only when positioned at regular lattice sites of the basic semiconductor material, the dopants have to be “activated,” that is, to be moved to lattice sites. The fraction of dopant atoms finally positioned at lattice sites determines the degree of activation obtained. The activation is achieved by heating the semiconductor material in order to endow the dopants with sufficient energy to replace a lattice atom at a lattice site or to occupy an empty lattice site. During the heat treatment, respective lattice defects may also be repaired. However, the advantages of dopant activation and lattice re-crystallization come along with dopant diffusion, since the dopant atoms tend to move through the crystal in order to reduce the existing concentration gradients. Thus, each high temperature process may contribute to a dopant diffusion, the degree of which is determined by the temperature and time of the heat treatment. Thus, a thermal budget, i.e., the integral of the product of temperature and process time, has to be maintained as low as possible, in particular for sophisticated transistors requiring abrupt PN junctions.

Irrespective of the technological approach used, sophisticated spacer techniques are usually necessary to create the highly complex dopant profile and to serve as a mask in forming metal silicide regions in the gate electrode and the drain and source regions in a self-aligned fashion. The metal silicide regions are provided for improving the contact resistance of the drain and source regions, as well as the conductivity of the gate electrode, when formed from polysilicon, since some metal silicides exhibit an increased conductivity compared to even highly doped silicon. It turns out that different metal silicides, as well as their position, may have different influences on the performance of NMOS transistors and PMOS transistors, respectively. For instance, locating the metal silicide region more closely to the channel region of an NMOS transistor enhances the performance thereof, while the performance of a PMOS transistor may be improved by using nickel silicide instead of cobalt silicide, which is a frequently used material. However, nickel silicide tends to form so-called “piping” defects, that is, silicide “stingers,” which may extend into the channel region, thereby possibly not allowing the nickel silicide to be located near the channel region as closely as desired without unduly affecting the transistor behavior. It is believed that some of the difficulties in forming metal silicide regions arise from the diffusion behavior of the metal in the polycrystalline or crystalline silicon in the drain and source regions and the gate electrode. Thus, in some approaches, the respective semiconductor regions may be amorphized prior to depositing the respective refractory metal in order to improve the diffusion behavior of the metal and the silicon during a subsequent reaction for forming a first phase of metal silicide. Thereafter, a further heat treatment may be performed at temperatures of approximately 400-600° C. that results in a transformed phase of the metal silicide having the desired low resistivity and/or the required thermal stability.

Since the continuous size reduction of the critical dimensions, i.e., the gate length of the transistors, necessitates the adaptation of process techniques concerning the formation of shallow PN junctions having steep concentration gradients, the processes performed after the formation of the implantation regions, such as the silicidation processing, may also be affected by these adaptations, while at the same time the silicidation process may have an influence on the finally obtained characteristics of the PN junctions, since, for example, interface roughness, silicide pipes and increased dopant diffusion may reduce the performance of the shallow PN junctions.

The present invention is directed to various methods for solving, or at least reducing the effects of, some or all of the aforementioned problems.

### SUMMARY OF THE INVENTION

The following presents a simplified summary of the disclosed subject matter in order to provide a basic understanding of some aspects of the subject matter disclosed herein. This summary is not an exhaustive overview of the technology disclosed herein. It is not intended to identify key or critical elements of the invention or to delineate the scope of the invention. Its sole purpose is to present some concepts in a simplified form as a prelude to the more detailed description that is discussed later.

Generally, the present invention is directed to a technique that provides enhanced transistor characteristics and may have the potential for reducing process complexity by performing a high temperature anneal process, which may result in an increased degree of dopant activation, after a silicidation process. In some illustrative embodiments, the anneal process is performed as a short irradiation process, wherein heating the respective transistor areas is restricted to a short time interval of approximately 0.1 seconds and significantly less, thereby maintaining unwanted dopant diffusion during the additional activation process at a low level. Moreover, the late anneal process may provide significant advantages in the silicide processing, since the respective transistor areas may remain in a substantially amorphous state, which may lead to increased process uniformity during the silicide formation. Consequently, the advantages obtained by a short dopant activation with reduced diffusion activity may be combined with the silicide processing to enhance the uniformity thereof and/or reduce process complexity.

According to one illustrative embodiment disclosed herein, a method comprises forming a drain region and a source region in a semiconductor layer and forming a metal silicide region in the drain and source regions. Furthermore, at least a portion of a dopant activation process is performed after forming the metal silicide region.

According to another illustrative embodiment, a method comprises forming a metal silicide region in drain and source regions of a transistor and annealing the drain and source regions and the metal silicide region for a time interval of less than approximately 0.1 seconds at a temperature of approximately 800° C. and higher.

### BRIEF DESCRIPTION OF THE DRAWINGS

The invention may be understood by reference to the following description taken in conjunction with the accompanying drawings, in which like reference numerals identify like elements, and in which:

FIGS. 1a-1c schematically illustrate cross-sectional views of a transistor element during various manufacturing stages in forming metal silicide regions and activating dopants, at least partially, after the metal silicide formation, as disclosed herein;

FIG. 1d schematically illustrates a system for performing a short duration anneal process on the basis of laser radiation that may be used for activating dopants with suppressed diffusion activity as disclosed herein; and

FIGS. 2a-2c schematically illustrate cross-sectional views of a transistor element during various manufacturing stages, wherein a corresponding anneal process with suppressed diffusion is performed at a later manufacturing stage, as disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure addresses the problem of forming advanced shallow drain and source regions with steep dopant concentration gradients at the respective PN junctions in order to increase transistor performance with respect to, for instance, leakage currents, while at the same time the series resistance of the respective transistor terminals may be decreased by forming highly advanced metal silicide regions in the respective transistor areas. For this purpose, appropriate anneal techniques, such as laser-based or flash-based anneal processes, providing the potential for annealing device regions within short time intervals, for instance at an interval of significantly less than one second, as is a typical duration of conventional rapid thermal annealing (RTA) processes, in order to reduce or substantially avoid diffusion of dopants, while nevertheless providing a high degree of dopant activation. The enhanced activation process may be efficiently combined with the silicidation processing in order to provide enhanced process flexibility and/or to increase the efficiency of the activation process by providing more uniform optical characteristics of the respective device areas to be annealed due to the presence of the metal silicide. In some illustrative embodiments, the activation process may be performed after an initial silicidation step and may be used as a silicide transformation treatment in order to obtain a desired low ohmic phase and/or a higher thermal stability of the respective metal silicide. Consequently, the overall process complexity may not increase, since a separate silicide transformation anneal process may be omitted, while nevertheless an increased degree of dopant activation may be achieved. In other illustrative embodiments, the metal silicide formation may be performed on the basis of a substantially amorphous semiconductor material, thereby providing enhanced process uniformity due to a more uniform diffusion behavior, which may significantly suppress the creation of silicide defects as may be encountered in conventional techniques, for instance in the form of interface roughness, nickel silicide pipes and the like. Consequently, the advantages of an increased activation level may be combined with enhanced performance of the respective metal silicides.

It should be appreciated that the subject matter disclosed herein is highly advantageous in the context of advanced transistor elements having critical dimensions, such as a gate length of 90 nm and even significantly less, such as 60 nm or less, since, in these cases, shallow dopant profiles with steep or abrupt PN junctions may be required at high dopant concentrations so that the corresponding thermal budget during the manufacturing process is extremely limited, wherein even conventional rapid thermal anneal techniques for dopant activation requiring a time interval of one second may no longer be appropriate. The principles of the subject matter disclosed herein may, however, also be advantageously used in less critical applications in order to provide enhanced process flexibility, for instance, in view of the silicidation processing.

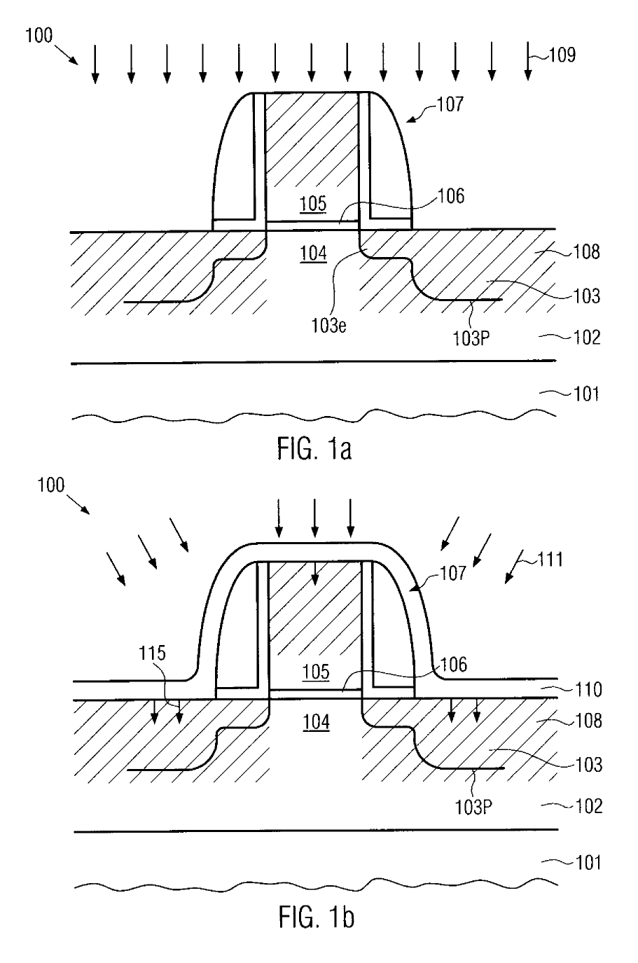

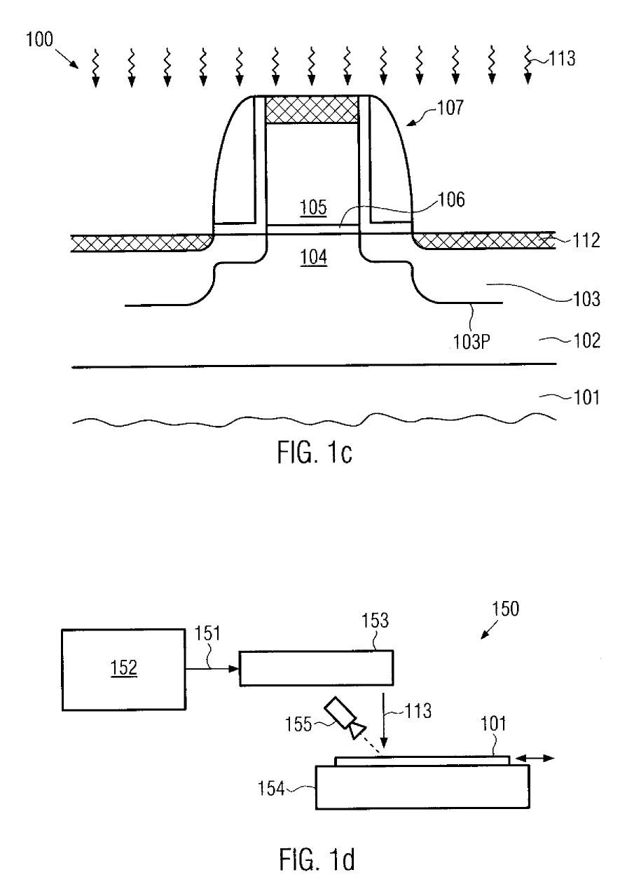

FIG. 1a schematically illustrates a semiconductor device 100, which, in the embodiment illustrated, may represent a field effect transistor, while, in other illustrative embodiments, the semiconductor device 100 may represent any circuit element requiring the formation of a PN junction in specified device areas. For instance, the semiconductor device 100 may represent a bipolar transistor, a capacitor, a P-channel transistor, an N-channel transistor, a diode and the like. The semiconductor device 100 may comprise a substrate 101, which may represent any appropriate substrate for providing an adequate semiconductor layer 102 for forming therein and thereon respective circuit elements. For instance, the substrate 101 may represent a bulk silicon substrate having formed thereon an appropriate silicon-based semiconductor layer, such as a silicon layer comprising a certain amount of germanium and/or comprising a certain amount of carbon and the like. In other illustrative embodiments, the substrate 101 may represent any appropriate carrier material for providing thereon the semiconductor layer 102. For instance, the substrate 101 may represent, in combination with the semiconductor layer, a silicon-on-insulator (SOI) type substrate, wherein the semiconductor layer 102 may be located on a respective buried insulating layer (not shown). Furthermore, in the manufacturing stage shown in FIG. 1a, the semiconductor device 100 may comprise a doped region 103, the shape of which may be determined by device requirements. For instance, in one illustrative embodiment, the device 100 may represent a field effect transistor in which a channel region 104 is defined by respective drain and source regions, such as the doped region 103. In advanced applications, a channel length, i.e., the horizontal extension of the channel region 104, may be in the range of approximately 90 nm and significantly less, such as 60 nm and less, while a vertical dimension of the doped regions 103, i.e., for field effect transistors the drain and source regions, may range from approximately 10 nm or less to several tenths of nanometers, depending on the transistor architecture.

As previously explained, in advanced applications, high dopant concentrations may be required, for instance at a level of 10¹⁹ atoms/cm³ or significantly higher with a moderately steep concentration gradient at the respective PN junctions 103P, which may be considered as an interface area between the doped region 103 and the channel region 104, which may be inversely doped or undoped, depending on device requirements. Furthermore, a gate electrode 105 may be provided above the channel region 104 and may be separated therefrom by a gate insulation layer 106, when the device 100 represents a field effect transistor. The gate insulation layer 106 may be comprised of any appropriate dielectric material, such as silicon dioxide, silicon nitride, silicon oxynitride, dielectric materials having a high dielectric constant, for instance a dielectric constant of 10 or significantly higher, or the gate insulation layer 106 may be comprised of a plurality of different materials or layers in order to provide the desired capacitive coupling to the channel region 104 on the basis of a tolerable level of leakage currents. For instance, in sophisticated applications, the gate insulation layer 106 may be comprised of silicon dioxide having a thickness of approximately 1-5 nm. The gate electrode 105 may be comprised, in this manufacturing stage, of any appropriate material, such as polycrystalline silicon, including a specific amount of dopant concentration and the like. Moreover, a corresponding sidewall spacer structure 107 may be formed on the side-walls of the gate electrode 105, wherein it should be appreciated that the specific configuration of the spacer structure 107 may depend on process and device requirements, wherein a plurality of individual spacer elements may be provided. It should further be appreciated that the transistor configuration shown in FIG. 1a is of illustrative nature only, and various design alternatives may be contemplated, such as transistor configurations having raised drain and source regions, i.e., doped regions 103, wherein a surface of the respective doped regions 103 may extend above a height level defined by the gate insulation layer 106. In other cases, the doped regions 103 may be recessed with respect to the gate insulation layer 106 and/or the doped regions 103 may be comprised of different semiconductor materials, such as silicon/germanium, silicon/carbon and the like, wherein these semiconductor compounds may be provided in a substantially relaxed lattice configuration or in a strained lattice configuration, depending on device requirements. In still other illustrative embodiments, the doped region 103 may be substantially formed in this manufacturing stage as a substantially amorphized semiconductor material, as indicated by the hatched area 108.

A typical process flow for forming the semiconductor device 100 may comprise the following processes. After providing the substrate 101 having formed thereon the semiconductor layer 102, any required process steps may be performed, such as the formation of isolation structures (not shown), the introduction of dopants into the semiconductor layer 102 as is required for the device 100 under consideration, such as implanting respective dopant species in order to define a locally required dopant concentration in the semiconductor layer 102, and the like. For example, when the device 100 represents a MOS transistor, any well-established MOS technologies may be used for this purpose. Thereafter, the semiconductor layer 102 may be appropriately masked in order to selectively introduce a dopant species, for instance by means of an ion implantation process 109 or any other appropriate technique. In one illustrative embodiment, masking the semiconductor layer 102 may be performed by forming the gate electrode 105 and the gate insulation layer 106 in accordance with well-established techniques, including the formation of an insulating layer followed by the deposition of an appropriate gate electrode material, which may be subsequently patterned on the basis of lithography and advanced etch techniques. Thereafter, sidewall spacers, if required, may be formed on sidewalls of the gate electrode 105 based on well-established deposition and etch techniques so as to appropriately determine the lateral profiling of the dopant concentration in the doped region 103. For example, by providing a respective spacer structure, such as the sidewall spacer structure 107 during the ion implantation process 109, the lateral offset of the respective PN junction 103P from the gate electrode 105 may be adjusted, which therefore results in a corresponding adjustment of the length of the channel region 104. In other cases, the semiconductor layer 102 adjacent to the respective spacer structure of the gate electrode may be recessed and may be refilled, at least partially, or may be overfilled with an appropriate semiconductor material, which may comprise a dopant species, if required. Typically, at least at some manufacturing stages in forming the doped region 103, an ion implantation process, such as the process 109, may be employed.

For instance, so-called extension regions, indicated as 103e, frequently may be used in combination with sophisticated field effect transistors, which may be formed by ion implantation, even if other portions of the doped regions 103 may receive the respective dopant species by epitaxial growth process and the like. Since the position of the PN junction 103P and thus the shaping of the respective doped region 103 or 103e may significantly affect the overall performance of the device 100, as previously explained, implantation-induced inaccuracies, such as channeling effects and the like, may be significantly reduced by performing a pre-amorphization process, for instance based on an appropriate ion implantation process in order to form the substantially amorphized portion 108. However, it should be understood that an amorphization process is not required in all embodiments. Consequently, the doped region 103 may be formed with a desired high precision as required for highly scaled semiconductor devices, even if the ion implantation process 109 is used for introducing at least a portion of the dopants, wherein, in some illustrative embodiments, the re-crystallization and activation of the dopants in the doped region 103 may be performed in a later stage of the manufacturing process in order to provide the amorphized portion 108 also during a silicidation process, as will be described later on. Consequently, the ion implantation process 109 based on the respective manufacturing stage of the sidewall spacer structure 107 may be performed so as to obtain the desired size and shape and concentration for the doped region 103.

In some illustrative embodiments, when a high degree of compatibility with conventional process strategies is to be maintained, after the formation of the doped region 103, an appropriately designed heat treatment, for instance on the basis of a rapid thermal anneal process, may be performed in order to activate dopants and/or re-crystallize, at least partially, implantation-induced lattice damage. For instance, in some cases, a moderately low anneal temperature may be used, for instance in the range of approximately 600-800° C., during which dopant diffusion may be moderately low due to the relatively low temperature, while the corresponding energy transferred to the crystal atoms may suffice to efficiently re-crystallize at least some of the doped region 103. Moreover, a certain degree of activation may also take place. A corresponding process sequence may be advantageous, when a substantially re-crystallized semiconductor layer 102 may be required for the further processing. In other cases, advanced anneal techniques such as laser-based processes or flash-based processes may be performed, possibly in combination with a preceding or subsequent or concurrent re-crystallization, in order to obtain a high degree of dopant activation. For example, a flash-based anneal process, in which a radiation pulse having a moderately broad wavelength range is used for irradiating the device 100, i.e., the semiconductor layer 102, on the basis of a time interval of several microseconds and less, possibly in combination with a low temperature anneal process, as previously described, may be used to also provide a basic preheating of the layer 102. In other illustrative embodiments, a substantially monochromatic light may be supplied by an appropriate laser source in order to efficiently activate dopants in the doped region 103.

FIG. 1b schematically illustrates the semiconductor device 100 in a further advanced manufacturing stage, wherein, in this illustrated embodiment, it may be assumed that a significant activation and re-crystallization may not have been performed, so that the corresponding substantially amorphous portions 108 are still present in the semiconductor layer 102. Moreover, a layer of refractory metal, such as cobalt, nickel, platinum and the like, or any combination thereof, indicated as 110, may be formed on the doped region 103 and other exposed surface portions of the semiconductor device 100. In the illustrative embodiment as depicted in FIG. 1b, the metal layer 110 may also be formed on the gate electrode 105 and the sidewall spacer structure 107. The metal layer 110 may be formed on the basis of any appropriate deposition technique, including sputter deposition, chemical vapor deposition (CVD) and the like. Thereafter, a heat treatment 111 may be performed with appropriately selected temperature and duration in order to initiate a chemical reaction with silicon contained in the doped region 103 and in the gate electrode 105, when comprised of silicon. The process parameters of the heat treatment 111 may depend on the specific type of metal used, wherein, for instance for nickel, moderately low temperatures, such as approximately 200-600° C., may be used for generating a nickel silicide. In other cases, temperatures in the range of approximately 500-700° C. may be used in order to form, for example, cobalt silicide during the process 111. During the silicidation, the diffusion behavior of the respective metal atoms and silicon atoms, indicated by arrows 115, may be different compared to a substantially crystalline semiconductor material or a substantially polycrystalline semiconductor material and may therefore provide enhanced uniformity of the resulting metal silicide. Thus, corresponding irregularities at interfaces between metal silicide and the remaining semiconductor material may be significantly reduced, thereby improving sheet resistance and/or significantly reducing the formation of metal silicide protrusions, as may be known under the term “nickel silicide pipes,” which may have the potential for bridging the respective PN junctions, in particular when semiconductor devices are considered that require extremely shallow PN junctions.

FIG. 1c schematically illustrates the semiconductor device after the completion of the process 111. Hence, the device 100 may comprise respective metal silicide regions 112 in the doped region 103 and, if provided, in the gate electrode 105. Moreover, in one illustrative embodiment, the semiconductor device 100 may be subjected to an anneal process 113 for activating dopants in the doped regions 103, while substantially suppressing or reducing unwanted diffusion of dopants in the vicinity of the PN junctions 103P. In one illustrative embodiment, the duration of applying heat to the doped regions 103 on the basis of radiation, such as light in an appropriate wavelength or wavelength range, is restricted to a time interval of 0.1 seconds and significantly less, while a temperature obtained in the doped region 103 may be at least 800° C. and significantly higher in order to provide sufficient activation energy for positioning dopant atoms at lattice sites of the basic semiconductor material, while diffusion of dopants is suppressed due to the shortness of the treatment 113. In illustrative embodiments, the corresponding duration of applying heat by radiation by means of the process 113 is several milliseconds to several microseconds, while, in other embodiments, radiation pulses of less than 1 microsecond may be used. In this case, any dopant diffusion is substantially negligible and hence the dopant gradient at the PN junctions 103P is substantially maintained.

Furthermore, in some illustrative embodiments, the finally obtained anneal temperature may exceed approximately 1000° C. and even higher, such as 1300° C. and even higher, wherein the substantially amorphized portion 108 is also re-crystallized to a high degree. Moreover, in some illustrative embodiments, the anneal treatment 113 may also provide a desired transformation of the metal silicide in the regions 112 in order to obtain the required characteristics, for instance with respect to resistivity, thermal stability and the like. As previously explained, in many silicidation regimes, a thermal treatment may be required after the actual chemical reaction to adjust the characteristics of the metal silicide. For instance, cobalt silicide may be formed as cobalt monosilicide at less elevated temperatures and may be converted into cobalt disilicide, having a significantly lower resistance, by an anneal process at higher temperatures which may, for instance, be performed after the removal of any excess metal from undesired surface portions, such as the sidewall spacer structure 107. In the case of nickel silicide, two different types of silicide may be generated, such as nickel monosilicide, having a low resistivity, and nickel disilicide, having a significantly higher resistance. Contrary to cobalt, nickel disilicide may form at moderately low temperatures, wherein the degree of generating nickel disilicide may depend on the diffusion characteristics and the like. Consequently, after removing any non-reacted metal, a so-called transformation heat treatment is frequently performed in order to adjust the required characteristics. Hence, in some embodiments, the corresponding silicide transformation may also be accomplished during the anneal process 113, thereby reducing process complexity, since a separate transformation treatment may be omitted.

In other illustrative embodiments, a specific type of transformation heat treatment may be performed prior to the anneal process 113, for instance if a less dynamic behavior of the metal silicide during the transformation phase may be required, for instance when an additional generation of cobalt disilicide is considered inappropriate during the process 113, due to a further consumption of additional silicon in the doped regions 103. In this case, the respective metal silicide 112 may at least be thermally stabilized during the process 113, while a significant alteration of the stoichiometric ratio of the silicide may be avoided.

Consequently, during the anneal process 113, an even further increased degree of dopant activation may be achieved, if a previous activation has already taken place, or an efficient dopant activation may be achieved, for instance in combination with an efficient re-crystallization of the substantially amorphized portion 108, if still present during the process 113, while at the same time, in some illustrative embodiments, the transformation of the metal silicide regions 112 into an appropriate configuration may be accomplished. Moreover, the provision of the metal silicide 112 prior to the anneal process 113, which is based on the irradiation of an appropriate beam of radiation, may enhance the process uniformity of the process 113, since the metal silicide 112 may effectively absorb the radiation and efficiently conduct heat into the lower-lying semiconductor areas. Consequently, a high degree of uniformity of the activation and re-crystallization and thus of the resulting characteristics of the doped regions 103 may be obtained.

FIG. 1d schematically illustrates a system 150 for performing the anneal process 113. The system 150 may comprise an appropriate radiation source 152, such as a laser source which may provide a continuous or pulsed laser beam 151. Moreover, an appropriate beam shaping system 153 may be provided in order to establish appropriate beam characteristics, that is, a specific beam shape and energy density, which may be accomplished on the basis of well-established techniques. Thus, radiation appropriate for the anneal process 113 may be provided at an output of the beam shaping system 153, which may further be configured to direct the resulting radiation, such as the radiation of the process 113, onto a substrate holder 154, which may for instance be provided in the form of a scan system. Moreover, a measurement system 155, which may include a temperature sensor, a power detector and the like, may be provided to detect a status of a substrate positioned on the scan system 154, such as the substrate 101 having formed thereon the semiconductor device 100.

During operation of the device for performing the anneal process 113, the substrate 101 may be positioned on the respective scan system 154, which may appropriately adjust the relative position between the radiation 113, exiting the beam shaping system 153, and the position on the substrate 101. Moreover, the measurement system 155 may provide respective data in order to detect and monitor the output power emitted by the beam shaping system 154 and the actually obtained temperature at the irradiated site at the substrate 101. Thereafter, the substrate may be irradiated such that the radiation 113 and thus the time of actively heating the exposed site of the substrate 101 is significantly less than approximately 0.1 seconds, which may be accomplished by using short radiation pulses and/or using a high scan speed when, for instance, a continuous radiation is used. For example, anneal times, that is, actively supplying radiation energy, of several milliseconds or less and even several microseconds and less, may be generated in order to effectively activate the dopants while suppressing dopant diffusion. During the anneal process 113, the radiation may be, at least partially, absorbed and partially result in kinetic energy for the dopants and lattice atoms for activation and re-crystallization, wherein the heat may then be dissipated into the “depth” of the substrate 101, without significantly raising the temperature thereof. For example, the backside of the substrate 101 may remain at a temperature of approximately 100° C. and even less. On the other hand, high temperatures may be locally generated in the semiconductor device 100, such as temperatures up to the melting temperature of silicon, if required.

It should be appreciated that the system 150 may be considered as a representative example of an available system for performing the anneal process 113 in order to obtain a desired high temperature range of 800° C. and significantly higher at an effective irradiation time of 0.1 seconds and significantly less. In other systems, the light source 152 may represent a pulsed flash lamp emitting a moderately broad wavelength range, wherein, depending on the system configuration, the substrate 101 may be irradiated as a whole or may be irradiated partially, as is shown in FIG. 1d.

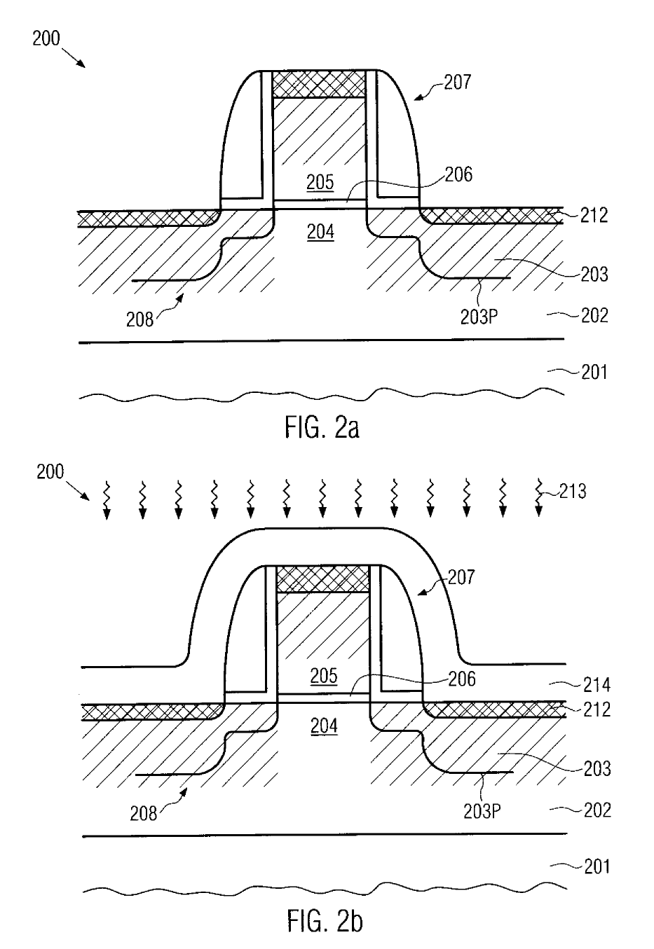

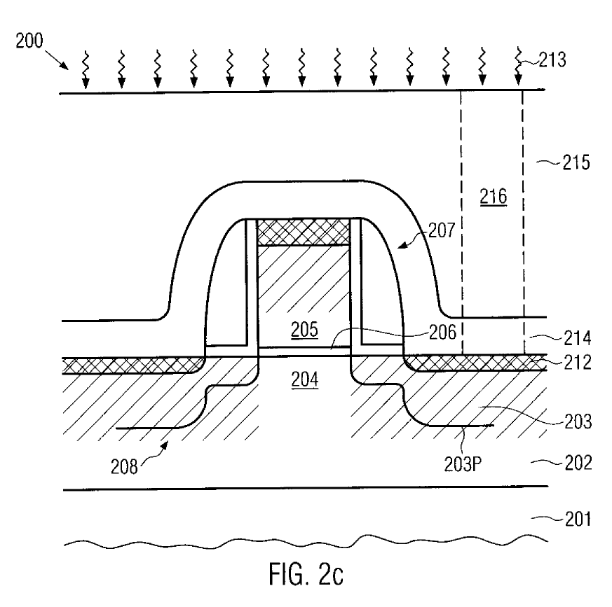

With reference to FIGS. 2a-2c, further illustrative embodiments will now be described in more detail, wherein a corresponding anneal process may be performed in a later manufacturing stage, additionally or alternatively compared to the process flow as described with reference to FIGS. 1a-1c.

FIG. 2a schematically illustrates a semiconductor device 200 which may represent any appropriate circuit element requiring the formation of a PN junction, as is also previously discussed with reference to the device 100. In the illustrative example shown, the device 200 may represent a field effect transistor having substantially the same components as previously described with reference to the device 100. Hence, the semiconductor device 200 may comprise a substrate 201 having formed thereon a semiconductor layer 202 including a doped region 203, for instance a drain region or a source region, including, in this manufacturing stage, respective metal silicide regions 212. Moreover, a gate electrode 205 may be provided and may be separated from a channel region 204 by a gate insulation layer 206. Furthermore, a sidewall spacer structure 207 may be provided on sidewalls of the gate electrode 205. Regarding a manufacturing sequence for forming the device 200 as shown in FIG. 2a, the same criteria apply as previously discussed with reference to the device 100. In some illustrative embodiments, the doped regions 203 may still be in a substantially amorphous state, indicated as the hatched area 208, thereby providing respective advantages in forming the metal silicide regions 212 as previously described.

In some illustrative embodiments, the metal silicide regions 212 may have been subjected to an appropriate transformation anneal process in order to provide respective characteristics, while, in still other illustrative embodiments, a corresponding transformation process may not have been performed.

FIG. 2b schematically illustrates the semiconductor device 200 after the formation of an insulating layer 214 which may be comprised of any appropriate material, such as silicon nitride, silicon dioxide or any other material. Moreover, the device 200 may be exposed to a heat treatment 213, such as a treatment having substantially the same criteria as previously described for the treatment 113, in order to activate dopants in the doped region 203 and also to substantially re-crystallize the region 203, when it is still in a substantially amorphous state. Due to the provision of the insulating layer 214, a highly uniform optical behavior of the device 200 during the anneal process 213 may be achieved, thereby enhancing even more the uniformity of the process 213. For instance, the optical characteristics of the layer 214, such as material composition, thickness and the like, may be adjusted in order to obtain a high degree of absorption for enhancing the efficiency of the process 213. In other illustrative embodiments, the insulating layer 214 may be additionally designed so as to act as an etch stop layer for the formation of respective contact openings in a later manufacturing stage. In some illustrative embodiments, a transformation process for adjusting the characteristics of the metal silicide regions 212 may not have been performed or may have been performed in a substantially “incomplete” state, so as to induce further modifications in the metal silicide regions 212 during the process 213. For instance, a further generation of disilicide may be induced by the process 213, wherein, due to the enclosure of the metal silicide region 212 by the layer 214, a corresponding stress may be generated due to an additional silicon consumption, wherein the disilicide may occupy more volume compared to the initial silicide material 212 and the silicon material. The resulting stress may induce a corresponding strain in the adjacent channel region 204, thereby increasing the charge carrier mobility, at least for one type of charge carriers.

FIG. 2c schematically illustrates the semiconductor device 200 according to another illustrative embodiment, wherein, starting from the device 200 as shown in FIG. 2a, a substantially planar surface topography may be established prior to performing the anneal process 213. For instance, a dielectric layer stack may be provided, which may comprise the insulating layer 214 and an additional insulating layer 215, which, in one illustrative embodiment, may represent an interlayer dielectric material, such as silicon dioxide, while the insulating layer 214 may represent an etch stop layer. The layers 214 and 215 may be formed on the basis of well-established deposition techniques, followed by an appropriate planarization technique, such as chemical mechanical polishing (CMP) and the like. Hence, the optical response of the device 200 with respect to the anneal process 213 may thus be substantially determined by the substantially planarized layer 215 so that a highly uniform behavior during the irradiation of the device 200 may be achieved.

After the process 213, depending on the characteristics of the layers 215 and 214, at least the layer 215 may be removed, when the material thereof is inappropriate for an interlayer dielectric material, while, in other illustrative embodiments, respective contact openings 216 may be formed in the layers 215 and 214 on the basis of well-established lithography and etch techniques, wherein the respective contact openings 216 may be subsequently filled with any appropriate conductive material in order to establish a contact to the metal silicide region 212.

As a result, the subject matter disclosed herein provides a technique for forming semiconductor devices requiring sophisticated PN junctions in combination with metal silicide regions for reducing the series resistance of the respective PN junction. For this purpose, the activation of dopants may be, at least partially, performed after the silicidation process, thereby providing enhanced conditions for a laser-based or flash-based irradiation. Moreover, in some illustrative embodiments, the respective doped regions, such as drain and source regions of a transistor element, may substantially remain in their amorphous state during the silicidation process, thereby providing enhanced conditions during the silicidation process, since the diffusion of metal atoms and silicon atoms may be enhanced. Consequently, the resulting interface between the metal silicide and the semiconductor material may have a reduced degree of irregularities, such as nickel silicide pipes, increased surface roughness and the like. Furthermore, the transformation of the metal silicide into an appropriate configuration may also be accomplished during the late anneal process, thereby reducing the process complexity. In some illustrative embodiments, the laser-based or flash-based anneal process for activating the dopant may be combined with other anneal processes prior to the formation of the metal silicide regions to provide a high degree of compatibility with conventional process techniques. In other cases, the activation and re-crystallization of the doped region may be completely performed after the formation of a metal silicide, wherein, in some illustrative embodiments, the process may be performed at any later stage, wherein, in some cases, an additional layer, such as a contact etch stop layer, an interlayer dielectric material, may be provided in order to provide enhanced uniformity with respect to the optical response of the semiconductor device during the irradiation.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a doped region in a semiconductor layer to provide a PN junction in said semiconductor layer;
forming a metal silicide region in said doped region; and
performing at least a portion of a dopant activation process after forming said metal silicide region.

2. The method of claim 1, wherein performing said dopant activation process comprises annealing said doped region by irradiation of light with a duration of less than approximately 0.1 second.

3. The method of claim 2, wherein said irradiation of light is performed by using at least one of a flash lamp and a laser source.

4. The method of claim 1, further comprising performing an initial heat treatment for activating dopants and reducing lattice damage in said doped region, wherein said initial heat treatment is performed prior to forming said metal silicide region.

5. The method of claim 1, wherein forming said metal silicide region further comprises forming a refractory metal above said doped region and heating said refractory metal to initiate a chemical reaction with material of said doped region.

6. The method of claim 1, wherein said doped region is formed as substantially amorphized portions of said semiconductor layer.

7. The method of claim 6, wherein said metal silicide region is formed in said substantially amorphized portion.

8. The method of claim 1, further comprising forming a dielectric layer above said metal silicide region prior to performing said at least a portion of said dopant activation process.

9. The method of claim 1, wherein said doped region represents at least one of a drain region and a source region of a transistor element.

10. A method, comprising:
forming a metal silicide region in drain and source regions of a transistor; and
annealing said drain and source regions and said metal silicide region for a time interval of less than approximately 0.1 seconds at a temperature of approximately 800° C. and higher.

11. The method of claim 10, wherein said drain and source regions are formed in a substantially amorphous state and wherein forming said metal silicide region comprises forming said metal silicide region in said substantially amorphous drain and source regions.

12. The method of claim 10, wherein forming said metal silicide regions comprises forming a refractory metal layer on said drain and source regions and performing a heat treatment to initiate a chemical reaction between said refractory metal layer and material in said drain and source regions.

13. The method of claim 12, wherein said refractory metal layer comprises nickel.

14. The method of claim 10, further comprising annealing said drain and source regions prior to forming said metal silicide region.

15. The method of claim 10, further comprising forming an insulating layer above said transistor prior to annealing said drain and source regions and said metal silicide region.

16. The method of claim 15, wherein said insulating layer is provided with a substantially planar surface topography.

17. The method of claim 16, further comprising forming a contact in said insulating layer to connect to said metal silicide region.
